(19) United States
(12) Patent Application Publication
(10) Pub. No.: US 2026/0080942 A1
(43) Pub. Date: Mar. 19, 2026

(54) OPERATION METHOD AND SEMICONDUCTOR MEMORY DEVICE

(71) Applicant: Kioxia Corporation, Tokyo (JP)

(72) Inventors: Shoya SHIRAISHI, Kamakura Kanagawa (JP); Hiromitsu KOMAI, Kamakura Kanagawa (JP); Yuki ISHIZAKI, Odawara Kanagawa (JP)

(73) Assignee: Kioxia Corporation, Tokyo (JP)

(21) Appl. No.: 19/057,182

(22) Filed: Feb. 19, 2025

(30) Foreign Application Priority Data
Sep. 13, 2024 (JP) 2024-159059

(51) Int. Cl. G11C 16/08; G11C 16/10; G11C 16/26

(52) U.S. Cl. CPC G11C 16/08; G11C 16/102; G11C 16/26

(57) ABSTRACT

In general, according to one embodiment, an operation method using a first latch circuit including: first and second inverters each includes an input terminal coupled to first and second nodes respectively, and an output terminal coupled to the second and first nodes, respectively, the operation method comprising: storing first and second data in the first and second node by setting the first and second inverters to a driven state, wherein the second data is inverted data of the first data; reading the first data from the first node to a bus coupled to the first latch circuit by setting the first and second inverters to an undriven state; writing the first data based on the second data to the first node from which the first data is read by setting the first inverter to the driven state; and driving the second inverter after the first data is written.

### CROSS-REFERENCE TO RELATED APPLICATIONS

This application is based upon and claims the benefit of priority from Japanese Patent Application No. 2024-159059, filed Sep. 13, 2024, the entire contents of which are incorporated herein by reference.

### FIELD

Embodiments described herein relate generally to an operation method and a semiconductor memory device.

### BACKGROUND

A NAND flash memory is known as a semiconductor memory device capable of storing data in a non-volatile manner. The NAND flash memory includes a sense amplifier module, and reads data memorized in the memory and writes data to the memory.

### BRIEF DESCRIPTION OF THE DRAWINGS

FIG. 1 is a block diagram illustrating an example of the configuration of a memory system according to an embodiment.

FIG. 2 is a circuit diagram illustrating an example of the circuit configuration of a memory cell array included in the semiconductor memory device according to the embodiment.

FIG. 3 is a block diagram illustrating an example of the configuration of a sense amplifier module included in the semiconductor memory device according to the embodiment.

FIG. 4 is a circuit diagram illustrating an example of the circuit configuration of the sense amplifier module included in the semiconductor memory device according to the embodiment.

FIG. 5 is a circuit diagram illustrating an example of the circuit configuration of a latch circuit in the sense amplifier module included in the semiconductor memory device according to the embodiment.

FIG. 6 is a timing chart illustrating an example of the voltages of various signals during a first calculation process performed in the sense amplifier module of the semiconductor memory device according to the embodiment.

FIG. 7 is a table illustrating data held by each node and bus during a first calculation process performed in the sense amplifier module of the semiconductor memory device according to the embodiment.

FIG. 8 is a timing chart illustrating an example of the voltages of various signals during a second calculation process performed in the sense amplifier module of the semiconductor memory device according to the embodiment.

FIG. 9 is a table illustrating data held by each node and bus during the second calculation process performed in the sense amplifier module of the semiconductor memory device according to the embodiment.

FIG. 10 is a timing chart illustrating an example of the voltages of various signals during a third calculation process performed in the sense amplifier module of the semiconductor memory device according to the embodiment.

FIG. 11 is a table illustrating data held by each node and bus during the third calculation process performed in the sense amplifier module of the semiconductor memory device according to the embodiment.

FIG. 12 is a timing chart illustrating an example of the voltages of various signals during the first calculation process performed in the sense amplifier module of the semiconductor memory device according to the embodiment.

FIG. 13 is a timing chart illustrating an example of the voltages of various signals during the second calculation process performed in the sense amplifier module of the semiconductor memory device according to the embodiment.

FIG. 14 is a timing chart illustrating an example of the voltages of various signals during the third calculation process performed in the sense amplifier module of the semiconductor memory device according to the embodiment.

### DETAILED DESCRIPTION

In general, according to one embodiment, an operation method using a first latch circuit including: a first inverter that includes an input terminal coupled to a first node and an output terminal coupled to a second node; and a second inverter that includes an input terminal coupled to the second node and an output terminal coupled to the first node, the operation method comprising: storing first data in the first node and second data, which is inverted data of the first data, in the second node by setting the first inverter and the second inverter to a driven state; reading the first data from the first node to a bus coupled to the first latch circuit by setting the first inverter and the second inverter to an undriven state; writing the first data based on the second data to the first node from which the first data is read by setting the first inverter to the driven state; and driving the second inverter after the first data is written.

Embodiments will be described below with reference to the accompanying drawings. The drawings are schematic, and the dimensions and scales in the drawings are not necessarily the same as those of the actual products. In the description below, components having the same functions and configurations will be denoted by the same reference symbols. Where elements with similar configurations are specifically distinguished from one another, different letters or numbers may be appended to the same reference symbols.

In the description below, in a case in which a first element is described as being “coupled to” a second element, this includes a case where the first element is coupled to the second element indirectly via an intermediate element that is conductive at all times or at selected times, and a case where the first element is coupled directly to the second element without an intermediate element.

### 1. Configuration

### 1.1 Memory System

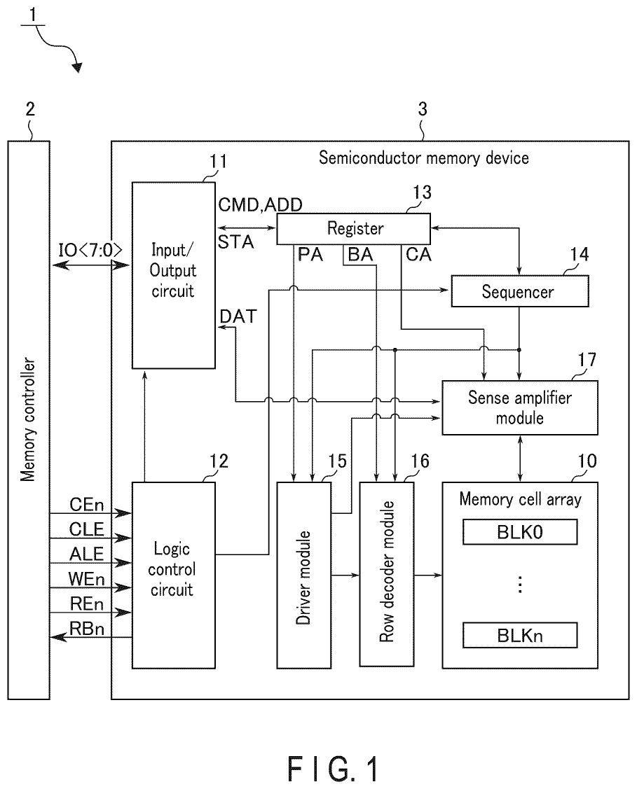

A semiconductor memory device according to an embodiment will be described. FIG. 1 is a block diagram illustrating an example of the configuration of a memory system according to an embodiment. The memory system 1 is a storage device configured to be coupled to an external host device (not shown). The memory system 1 is, for example, a memory card such as an SD™ card, a UFS (universal flash storage), or an SSD (solid state drive). The memory system 1 includes a memory controller 2 and a semiconductor memory device 3.

The memory controller 2 is implemented, for example, using an integrated circuit such as an SoC (system on a chip). The memory controller 2 controls the semiconductor memory device 3, based on a request from the external host device. Specifically, the memory controller 2 writes the data requested to be written by the external host device into the semiconductor memory device 3. Additionally, the memory controller 2 reads the data requested to be read by the external host device from the semiconductor memory device 3 and outputs it to the external host device.

The semiconductor memory device 3 is, for example, a memory that memorizes data in a volatile or non-volatile manner. In the description below, a case where the semiconductor memory device 3 is a NAND flash memory will be mentioned.

The communication between the memory controller 2 and the semiconductor memory device 3 conforms, for example, to the SDR (single data rate) interface, the toggle DDR (double data rate) interface, or the ONFI (open NAND flash interface). Signals including, for example, signals IO<7:0>, CEn, CLE, ALE, WEn, REn and RBn are exchanged between the memory controller 2 and the semiconductor memory device 3.

### 1.2 Semiconductor Memory Device

Next, the internal configuration of the semiconductor memory device 3 according to the embodiment will be described with reference to the block diagram illustrated in FIG. 1. The semiconductor memory device 3 includes, for example, a memory cell array 10, an input/output circuit 11, a logic control circuit 12, a register 13, a sequencer 14, a driver module 15, a row decoder module 16, and a sense amplifier module 17.

The memory cell array 10 includes a collection of a set of memory cell transistors and components coupled to the memory cell transistors. The memory cell array 10 includes a plurality of blocks BLK0 to BLKn (n is an integer of 1 or more). A block BLK is a collection of a plurality of memory cell transistors capable of memorizing data in a non-volatile manner. A block BLK is used, for example, as an erase unit when data memorized in the memory cell transistors is erased. The memory cell array 10 includes a plurality of bit lines and a plurality of word lines. Each memory cell transistor is associated, for example, with a combination of one bit line and one word line. A detailed configuration the memory cell array 10 will be described later.

The input/output circuit 11 is an interface circuit that controls the transmission and reception of signals IO<7:0> exchanged with the memory controller 2. A signal IO<7:0> is an 8-bit signal. The signal IO<7:0> includes, for example, data DAT, a command CMD, address information ADD, and status information STA. The input/output circuit 11 inputs and outputs data DAT between the sense amplifier module 17 and the memory controller 2. The input/output circuit 11 outputs each of the command CMD and address information ADD transferred from the memory controller 2 to the register 13. The input/output circuit 11 outputs the status information STA transferred from the register 13 to the memory controller 2.

The logic control circuit 12 is an interface circuit that receives signals CEn, CLE, ALE, WEn and REn input from the memory controller 2, and transmits a signal RBn to the memory controller 2. The logic control circuit 12 controls the input/output circuit 11 and the sequencer 14, based on the signals CEn, CLE, ALE, WEn and REn. For example, the logic control circuit 12 controls the sequencer 14, based on the signal CEn, to enable the semiconductor memory device 3. Based on the signals CLE and ALE, the logic control circuit 12 notifies the input/output circuit 11 that the signals 10<7:0> received by the input/output circuit 11 are a command CMD and address information ADD, respectively. The logic control circuit 12 instructs the input/output circuit 11 to input and output signals IO<7:0>, based on the signals WEn and Ren, respectively. In addition, the logic control circuit 12 outputs a signal RBn to the memory controller 2 indicating whether the semiconductor memory device 3 is in a ready state (a state in which it can accept commands from the outside) or in a busy state (a state in which it cannot accept commands from the outside).

The register 13 temporarily stores the command CMD, the address information ADD, and the status information STA. The command CMD includes, for example, instructions for causing the sequencer 14 to execute a read operation, a write operation, an erase operation, or the like. The address information ADD includes, for example, a block address BA, a page address PA, and a column address CA. For example, the block address BA, the page address PA, and the column address CA are used to select a block BLK, a word line, and a bit line, respectively. The status information STA is used to notify the memory controller 2 whether or not the operation has been completed normally. The status information STA is updated based on the control of the sequencer 14, and is transferred to the input/output circuit 11.

The sequencer 14 controls the overall operation of the semiconductor memory device 3. For example, the sequencer 14 controls the driver module 15, the row decoder module 16, and the sense amplifier module 17, or the like, based on the command CMD stored in the register 13. The sequencer 14 executes, for example, a read operation, a write operation, and an erase operation.

The driver module 15 generates a plurality of voltages of different magnitudes to be used in a read operation, a write operation, an erase operation, or the like. The driver module 15 supplies the generated voltages to the row decoder module 16 and the sense amplifier module 17, etc. The driver module 15 also applies the generated voltages to a signal line corresponding to a word line that is selected, for example, based on a page address PA stored in the register 13.

The row decoder module 16 selects one of the blocks BLK in the corresponding memory cell array 10, based on the block address BA held in the address register 13. The row decoder module 16 transfers, for example, a signal line voltage applied by the driver module 15 to the selected word line in the selected block BLK.

The sense amplifier module 17 includes a sense amplifier unit capable of determining data, based on the voltage of an associated bit line, a latch circuit for temporarily storing data, etc. In a write operation, the sense amplifier module 17 applies a predetermined voltage to each bit line in accordance with the write data DAT received from the input/output circuit 11. In a read operation, the sense amplifier module 17 determines the data stored in the memory cell transistor, based on the magnitude of the voltage on the bit line. Then, the sense amplifier module 17 transfers the determination result to the input/output circuit 11 as read data DAT.

### 1.3 Circuit Configuration of Memory Cell Array

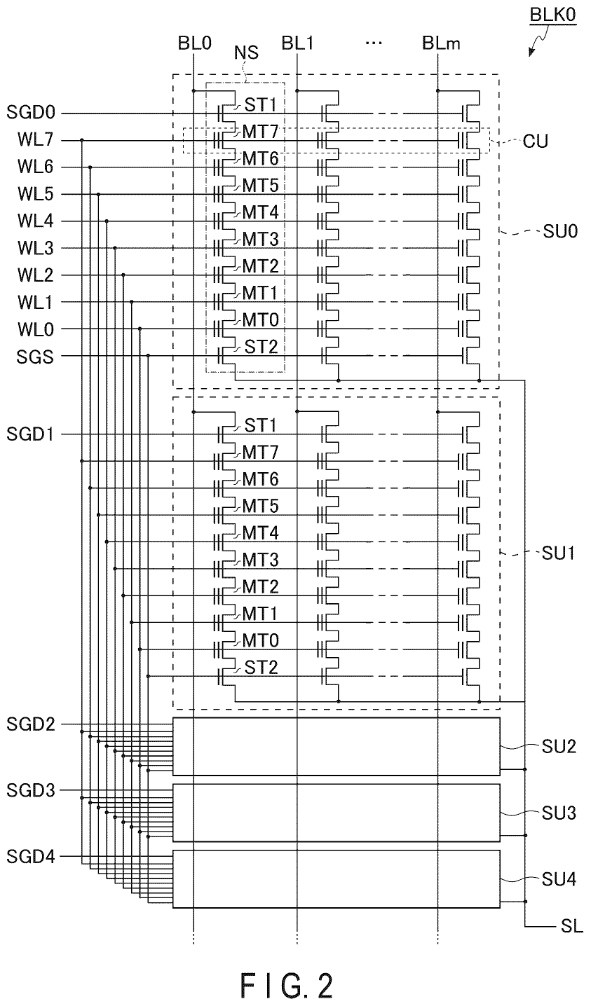

FIG. 2 is a circuit diagram illustrating an example of the circuit configuration of a memory cell array included in the semiconductor memory device according to the embodiment. FIG. 2 illustrates a block BLK0 as an example. The block BLK0 includes, for example, five string units SU0 to SU4.

Each string unit SU includes a plurality of NAND strings NS associated with bit lines BL0 to BLm, respectively (where m is an integer equal to or greater than 1). Each NAND string NS includes, for example, eight memory cell transistors MT0 to MT7 and select transistors ST1 and ST2. Each memory cell transistor MT includes a control gate and a charge storage film, and stores data in a non-volatile manner, based on the amount of charge in the charge storage film. Each of the select transistors ST1 and ST2 is used for selecting a string unit SU during various operations.

In each NAND string NS, the memory cell transistors MT0 to MT7 are coupled in series in this order. The drain of the select transistor ST1 is coupled to the associated bit line BL, and the source of the select transistor ST1 is coupled to the drain of the memory cell transistor MT7. The drain of the select transistor ST2 is coupled to the source of the memory cell transistor MT0, and the source of the select transistor ST2 is coupled to a source line SL.

The control gates of the memory cell transistors MT0 to MT7 in the same block BLK are coupled to word lines WL0 to WL7, respectively. The gates of the select transistors ST1 in the string units SU0 to SU4 are coupled to select gate lines SGD0 to SGD4, respectively. The gates of the select transistors ST2 included in the same block BLK are coupled to a select gate line SGS.

Different column addresses CA are assigned to the bit lines BL0 to BLm. Each bit line BL is shared among the NAND strings NS that are assigned the same column address CA across the plurality of blocks BLK. Each of the word lines WL0 to WL7 is provided for each block BLK. The source line SL is shared, for example, among the plurality of blocks BLK.

A set of memory cell transistors MT coupled to a common word line WL in one string unit SU will be referred to as a cell unit CU. For example, the storage capacity of the cell unit CU including memory cell transistors MT each storing 1-bit data is defined as “1 page data.” The cell unit CU may have a storage capacity of two page data or more in accordance with the number of bits of data stored in the memory cell transistor MT.

The circuit configuration of the memory cell array 10 included in the semiconductor memory device 3 according to the embodiment is not limited to the above. For example, the number of string units SU included in each block BLK may be designed to be an arbitrary number. The number of memory cell transistors MT included in each NAND string NS and the number of select transistors ST1 and ST2 may be designed to be arbitrary numbers.

### 1.4 Configuration of Sense Amplifier Module

### 1.4.1 Overview

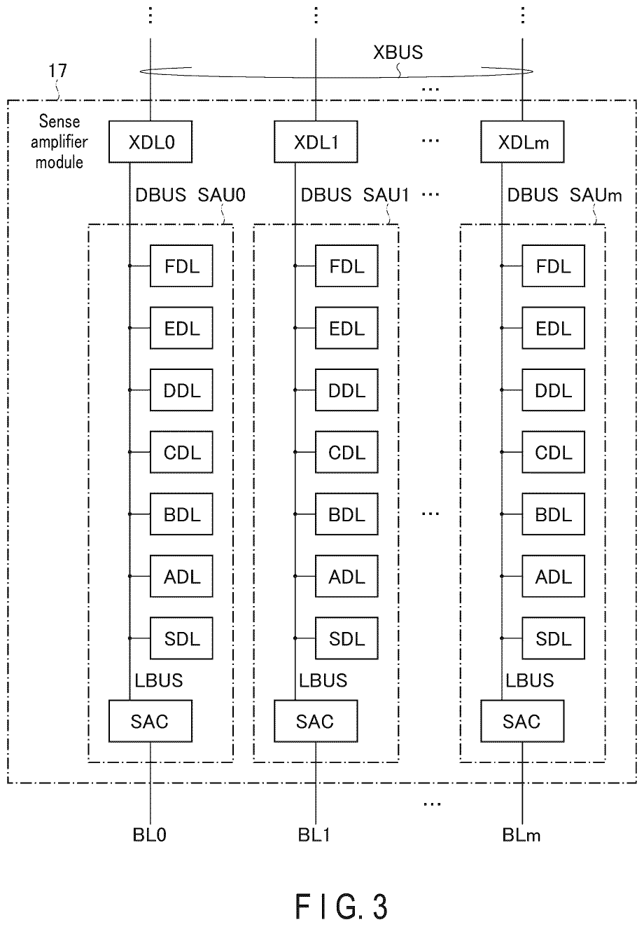

FIG. 3 is a block diagram illustrating an example of the configuration of the sense amplifier module included in the semiconductor memory device according to the embodiment.

As illustrated in FIG. 3, the sense amplifier module 17 includes sense amplifier units SAU0 to SAUm and latch circuits XDL0 to XDLm. The sense amplifier units SAU0 to SAUm and the latch circuits XDL0 to XDLm are associated with bit lines BL0 to BLm, respectively. In the description below, in a case where the sense amplifier units SAU0 to SAUm are not distinguished from each other, they will be referred to simply as a sense amplifier unit SAU. In a case where the latch circuits XDL0 to XDLm are not distinguished from each other, they will be referred to simply as a latch circuit XDL.

The sense amplifier unit SAU is, for example, a current sensing type sense amplifier unit that senses the current flowing through the bit line BL. The sense amplifier unit SAU senses the current flowing through the corresponding bit line BL and determines the state of a memory cell based on the sense result. Furthermore, the sense amplifier unit SAU transfers write data to the memory cell transistor MT via the corresponding bit line BL. The sense amplifier unit SAU may be a voltage sensing type sense amplifier unit that senses the voltage of the bit line BL.

Each sense amplifier unit SAU includes, for example, a sense circuit SAC and seven latch circuits SDL, ADL, BDL, CDL, DDL, EDL and FDL. The sense circuit SAC and the seven latch circuits SDL, ADL, BDL, CDL, DDL, EDL and FDL are commonly coupled to a bus LBUS. The number of latch circuits included in each sense amplifier unit SAU may be set to any number equal to or greater than two.

During a read operation, the sense circuit SAC senses the data read to the corresponding bit line BL and determines whether the read data is “0” data or “1” data. During a write operation, the sense circuit SAC applies a voltage to the bit line BL, based on the data stored in one of the latch circuits SDL, ADL, BDL, CDL, DDL, EDL and FDL.

The latch circuits SDL, ADL, BDL, CDL, DDL, EDL and FDL are circuits that store read data, write data, sense results, calculation results, and the like. For example, each of the latch circuits SDL, ADL, BDL, CDL, DDL, EDL and FDL stores one bit of data, which is either “0” data or “1” data. For example, during a read operation, data can be transferred from the sense circuit SAC to one of the latch circuits SDL, ADL, BDL, CDL, DDL, EDL and FDL. During a write operation, a voltage is applied to the bit line BL, based on the data stored in one or more of the latch circuits SDL, ADL, BDL, CDL, DDL, EDL and FDL.

The sense amplifier unit SAU performs, for example, an AND operation and an OR operation during a read operation and a write operation, using the data stored in the latch circuits SDL, ADL, BDL, CDL, DDL, EDL and FDL. The AND operation checks data stored in the plurality of latch circuits, and outputs “1” data if all the checked latch circuits store the “1” data, and outputs “0” data otherwise. The OR operation checks data stored in the plurality of latch circuits, and outputs “1” data if even one of the checked latch circuits stores the “1” data, and outputs “0” data otherwise.

The configuration of the sense amplifier unit SAU is not limited to this and can be modified in various ways. For example, the number of latch circuits included in the sense amplifier unit SAU can be designed based on the number of bits of data stored in one memory cell transistor MT.

The latch circuit XDL is coupled to corresponding sense amplifier unit SAU via a bus DBUS. The latch circuit XDL is coupled to the input/output circuit 11 via the bus XBUS, and transmits and receives data DAT.

### 1.4.2 Circuit Configuration

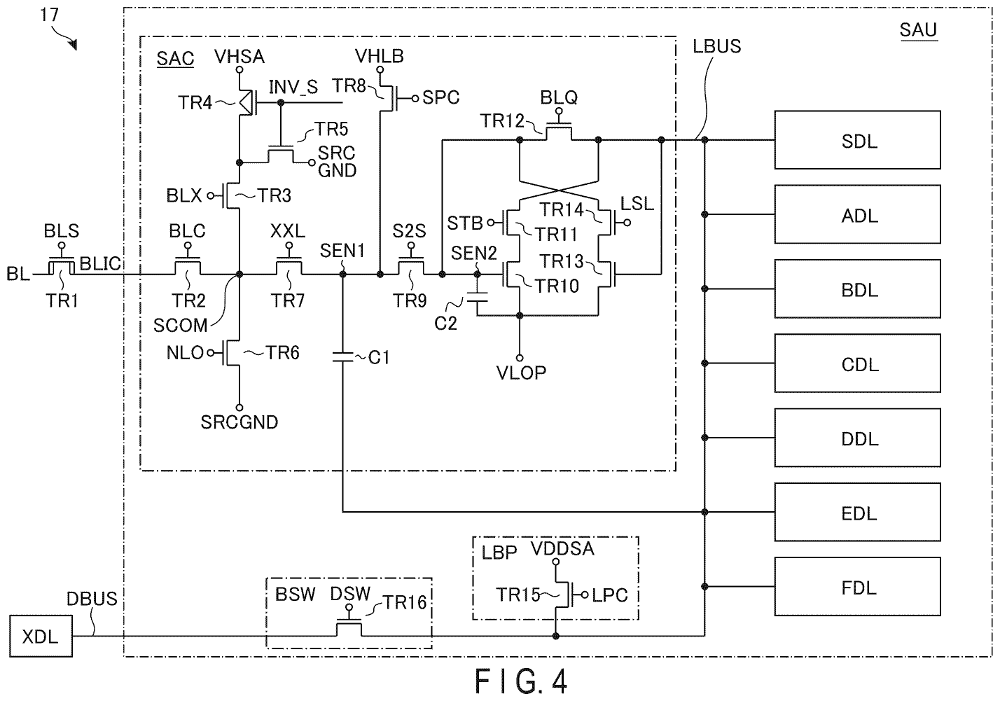

FIG. 4 is a circuit diagram illustrating an example of the circuit configuration of the sense amplifier module employed in the semiconductor memory device of the embodiment. FIG. 4 illustrates one sense amplifier unit SAU included in the sense amplifier module 17. The other sense amplifier units SAU have a configuration similar to that illustrated in FIG. 4. In the description below, in a case where the source and drain of a transistor are not distinguished, either the source or drain of the transistor will be referred to as a “first end” of the transistor, and the remaining end will be referred to as a “second end” of the transistor. The state in which the first end and the second end of the transistor are electrically coupled to each other via the transistor will be referred to as an “on state,” and the state in which they are electrically decoupled from each other via the transistor will be referred to as an “off state.”

As illustrated in FIG. 4, the sense amplifier module 17 includes, in addition to the configuration illustrated in FIG. 3, a transistor TR1, which is a high-voltage N-channel MOSFET (metal oxide semiconductor field effect transistor) corresponding to each sense amplifier unit SAU. In other words, in the sense amplifier module 17, the transistor TR1 is provided for each sense amplifier unit SAU.

A first end of the transistor TR1 is coupled to the corresponding bit line BL. A second end of the transistor TR1 is coupled to an interconnect BLIC. A control signal BLS is input to a gate of the transistor TR1. The control signal BLS is, for example, a signal generated by the sequencer 14. The transistor TR1 is used, for example, to prevent an excessively high voltage from being supplied to the sense amplifier unit SAU.

The sense amplifier unit SAU includes a sense circuit SAC, a precharge circuit LBP, a bus switch BSW, and seven latch circuits SDL, ADL, BDL, CDL, DDL, EDL and FDL.

The circuit configuration of the sense circuit SAC will be described. The sense circuit SAC includes transistors TR2 to TR14 and capacitance elements C1 and C2. The transistors TR2 to TR3 and TR5 to TR14 include N-channel MOSFETs. The transistor TR4 includes a P-channel MOSFET.

A first end of the transistor TR2 is coupled to the interconnect BLIC. A second end of the transistor TR2 is coupled to the node SCOM. A control signal BLX is input to a gate of the transistor TR2. The control signal BLX is, for example, a signal generated by the sequencer 14.

A first end of the transistor TR3 is coupled to the node SCOM. A second end of the transistor TR3 is coupled to a first end of the transistor TR4 and to a first end of the transistor TR5. A control signal BLX is input to a gate of the transistor TR3. The control signal BLX is, for example, a signal generated by the sequencer 14.

A voltage VHSA is applied to a second end of the transistor TR4. The voltage VHSA is, for example, a power supply voltage VCC. A gate of the transistor TR4 is coupled to a node INV_S, which will be described later.

A voltage SRCGND is applied to the second end of the transistor TR5. The voltage SRCGND is, for example, a ground voltage VSS. A gate of the transistor TR5 is coupled to the node INV_S described later.

A first end of the transistor TR6 is coupled to the node SCOM. A voltage SRCGND is applied to the second end of the transistor TR6. A control signal NLO is input to a gate of the transistor TR6. The control signal NLO is, for example, a signal generated by the sequencer 14.

A first end of the transistor TR7 is coupled to the node SCOM. A second end of the transistor TR7 is coupled to a node SEN1. A control signal XXL is input to a gate of the transistor TR7. The control signal XXL is, for example, a signal generated by the sequencer 14.

A first end of the transistor TR8 is coupled to the node SEN1. A voltage VHLB is applied to a second end of the transistor TR8. The voltage VHLB is, for example, the power supply voltage VCC. A control signal SPC is input to a gate of the transistor TR8. The control signal SPC is, for example, a signal generated by the sequencer 14.

A first end of the transistor TR9 is coupled to the node SEN1. A second end of the transistor TR9 is coupled to a node SEN2. A control signal S2S is input to a gate of the transistor TR9. The control signal S2S is, for example, a signal generated by the sequencer 14.

A first end of the transistor TR10 is coupled to a first end of the transistor TR11. A voltage VLOP is applied to a second end of the transistor TR10. The voltage VLOP is, for example, the ground voltage VSS. A gate of the transistor TR10 is coupled to the node SEN2.

A second end of the transistor TR11 is coupled to the bus LBUS. A control signal STB is input to a gate of the transistor TR11. The control signal STB is, for example, a signal generated by the sequencer 14.

A first end of the transistor TR12 is coupled to the node SEN2. A second end of the transistor TR12 is coupled to the bus LBUS. A control signal BLQ is input to a gate of the transistor TR12. The control signal BLQ is, for example, a signal generated by the sequencer 14.

A first end of the transistor TR13 is coupled to a first end of the transistor TR14. A voltage VLOP is applied to a second end of the transistor TR13. A gate of the transistor TR13 is coupled to the bus LBUS.

A second end of the transistor TR14 is coupled to the node SEN2. A control signal LSL is input to a gate of the transistor TR14. The control signal LSL is, for example, a signal generated by the sequencer 14.

One electrode of the capacitance element C1 is coupled to the node SEN1. The other electrode of the capacitance element C1 is coupled to the bus LBUS.

One electrode of the capacitance element C2 is coupled to the node SEN2. The voltage VLOP is applied to the other electrode of the capacitance element C2.

The circuit configuration of the precharge circuit LBP will be described. The precharge circuit LBP is a circuit that precharges the bus LBUS. The precharge circuit LBP includes a transistor TR15 including an N-channel MOSFET. A first end of the transistor TR15 is coupled to the bus LBUS. A voltage VDDSA is applied to a second end of the transistor TR15. The voltage VDDSA is, for example, a power supply voltage VCC. A control signal LPC is input to a gate of the transistor TR15. The control signal LPC is, for example, a signal generated by the sequencer 14.

The circuit configuration of the bus switch BSW will be described. The bus switch BSW is a switch that couples the bus LBUS and the bus DBUS to each other. The bus switch BSW is provided with a transistor TR16 including an N-channel MOSFET.

A first end of the transistor TR16 is coupled to the bus LBUS. A second end of the transistor TR16 is coupled to the bus DBUS. A control signal DSW is input to a gate of the transistor TR16. The control signal DSW is, for example, a signal generated by the sequencer 14.

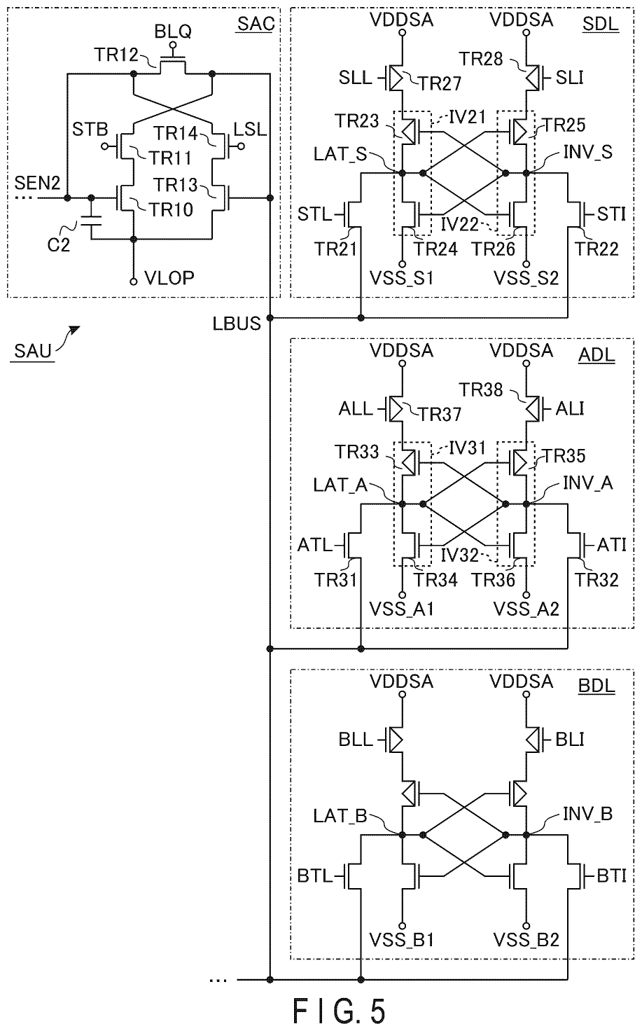

Next, the circuit configuration of the latch circuits SDL, ADL, BDL, CDL, DDL, EDL and FDL will be described with reference to FIG. 5. FIG. 5 is a circuit diagram illustrating an example of the circuit configuration of the latch circuits included in the sense amplifier module of the semiconductor memory device according to the embodiment. FIG. 5 illustrates the circuit configurations of the latch circuits SDL, ADL and BDL, and a portion of the sense circuit SAC. In the description below, the circuit configurations of the latch circuits SDL and ADL will be mentioned. The circuit configurations of the latch circuits BDL, CDL, DDL, EDL and FDL are similar to those of the latch circuits SDL and ADL.

The latch circuit SDL includes transistors TR21 to TR28. The transistors TR21, TR22, TR24 and TR26 include N-channel MOSFETs. The transistors TR23, TR25, TR27 and TR28 include P-channel MOSFETs.

A first end of the transistor TR21 is coupled to the bus LBUS. A second end of the transistor TR21 is coupled to a node LAT_S. A control signal STL is input to a gate of the transistor TR21. The control signal STL is, for example, a signal generated by sequencer 14.

A first end of the transistor TR22 is coupled to the bus LBUS. A second end of the transistor TR22 is coupled to the node INV_S. A control signal ST1 is input to a gate of the transistor TR22. The control signal ST1 is, for example, a signal generated by sequencer 14.

A first end of the transistor TR23 is coupled to the node LAT_S. A second end of the transistor TR23 is coupled to a first end of the transistor TR27. A gate of the transistor TR23 is coupled to the node INV_S.

A first end of the transistor TR24 is coupled to the node LAT_S. A voltage VSS_S1 is applied to a second end of the transistor TR24. The voltage VSS_S1 is, for example, the ground voltage VSS. A gate of the transistor TR24 is coupled to the node INV_S.

A first end of the transistor TR25 is coupled to the node INV_S. A second end of the transistor TR25 is coupled to a first end of the transistor TR28. A gate of the transistor TR25 is coupled to the node LAT_S.

A first end of the transistor TR26 is coupled to the node INV_S. A voltage VSS_S2 is applied to a second end of the transistor TR26. The voltage VSS_S2 is, for example, the ground voltage VSS. A gate of the transistor TR26 is coupled to the node LAT_S.

The voltage VDDSA is applied to a second end of the transistor TR27. A control signal SLL is input to a gate of the transistor TR27. The control signal SLL is, for example, a signal generated by the sequencer 14.

The voltage VDDSA is applied to a second end of the transistor TR28. A control signal SLI is input to a gate of the transistor TR28. The control signal SLI is, for example, a signal generated by the sequencer 14.

In a case where the transistor TR27 is in the on state, the transistors TR23 and TR24 function as an inverter IV21 that inverts the logic of the node INV_S and outputs it to the node LAT_S. In this case, the node INV_S can be considered to be the input end of the inverter IV21, and the node LAT_S can be considered to be the output end of the inverter IV21. The transistor TR27 controls the driving of the transistors TR23 and TR24 that function as the inverter IV21.

In a case where the transistor TR28 is in the on state, the transistors TR25 and TR26 function as an inverter IV22 that inverts the logic of the node LAT_S and outputs it to the node INV_S. In this case, the node LAT_S can be considered to be the input terminal of the inverter IV22, and node INV_S can be considered to be the output terminal of the inverter IV22. The transistor TR28 controls the driving of the transistors TR25 and TR26 that function as the inverter IV22.

The latch circuit SDL stores data by making the logic of the node LAT_S and the logic of the node INV_S exclusive. In a case where the voltage of the node LAT_S is at an “H” (high) level and the voltage of the node INV_S is at an “L” (low) level, the latch circuit SDL stores data of “1.” When the voltage of the node LAT_S is at the “L” level and the voltage of the node INV_S is at the “H” level, the latch circuit SDL stores data of “0.”

The latch circuit ADL includes transistors TR31 to TR38. The transistors TR31, TR32, TR34 and TR36 include N-channel MOSFETs. The transistors TR33, TR35, TR37 and TR38 include P-channel MOSFETs.

A first end of the transistor TR31 is coupled to the bus LBUS. A second end of the transistor TR31 is coupled to a node LAT_A. A control signal ATL is input to the node of the transistor TR31. The control signal ATL is, for example, a signal generated by the sequencer 14.

A first end of the transistor TR32 is coupled to the bus LBUS. A second end of the transistor TR32 is coupled to a node INV_A. A control signal ATI is input to the node of the transistor TR32. The control signal ATI is, for example, a signal generated by the sequencer 14.

A first end of the transistor TR33 is coupled to the node LAT_A. A second end of the transistor TR33 is coupled to a first end of the transistor TR37. A gate of the transistor TR33 is coupled to the node INV_A.

A first end of the transistor TR34 is coupled to the node LAT_A. A voltage VSS_A1 is applied to a second end of the transistor TR34. The voltage VSS_A1 is, for example, the ground voltage VSS. A gate of the transistor TR34 is coupled to the node INV_A.

A first end of the transistor TR35 is coupled to the node INV_A. A second end of the transistor TR35 is coupled to a first end of the transistor TR38. A gate of the transistor TR35 is coupled to the node LAT_A.

A first end of the transistor TR36 is coupled to the node INV_A. A voltage VSS_A2 is applied to a second end of the transistor TR36. The voltage VSS_A2 is, for example, the ground voltage VSS. A gate of the transistor TR36 is coupled to the node LAT_A.

A voltage VDDSA is applied to a second end of the transistor TR37. A control signal ALL is input to a gate of the transistor TR37. The control signal ALL is, for example, a signal generated by the sequencer 14.

A voltage VDDSA is applied to a second end of the transistor TR38. A control signal ALI is input to a gate of the transistor TR38. The control signal ALI is, for example, a signal generated by the sequencer 14.

In the case where the transistor TR37 is in the on state, the transistors TR33 and TR34 function as an inverter IV31 that inverts the logic of the node INV_A and outputs it to the node LAT_A. At this time, the node INV_A can be considered to be the input terminal of the inverter IV31, and the node LAT_A can be considered to be the output terminal of the inverter IV31. The transistor TR37 controls the driving of the transistors TR33 and TR34 that function as the inverter IV31.

In the case where the transistor TR38 is in the on state, the transistors TR35 and TR36 function as an inverter IV32 that inverts the logic of the node LAT_A and outputs it to the node INV_A. At this time, the node LAT_A can be considered to be the input terminal of the inverter IV32, and the node INV_A can be considered to be the output terminal of the inverter IV32. The transistor TR38 controls the driving of the transistors TR35 and TR36 that function as the inverter IV32.

The latch circuit ADL stores data in the state where the logic of the node LAT_A and the logic of the node INV_A are exclusive. In the case where the voltage of the node LAT_A is at the “H” level and the voltage of the node INV_A is at the “L” level, the latch circuit ADL stores “1” data. In the case where the voltage of the node LAT_A is at the “L” level and the voltage of the node INV_A is at the “H” level, the latch circuit ADL stores “0” data.

As described above, in the sense amplifier unit SAU, the sense circuit SAC and the latch circuits SDL, ADL, BDL, CDL, DDL, EDL and FDL can transmit and receive data to and from each other via the bus LBUS.

### 2. Operation

A description will be given of how the semiconductor memory device 3 according to the present embodiment performs calculation processes using the data stored in the latch circuits SDL, ADL, BDL, CDL, DDL, EDL and FDL included in the sense amplifier module 17, when data is written to the memory cell array 10. When data is written to the memory cell array 10, the sense amplifier module 17 according to the embodiment applies a voltage corresponding to the data to be written to the bit line BL corresponding to the memory cell to which the data is input. At this time, the sense amplifier unit SAU performs a first calculation process, a second calculation process, or a third calculation process, using the data stored in the latch circuits SDL, ADL, BDL, CDL, DDL, EDL and FDL. The details of each of the processes and the operation of the sense amplifier unit SAU during the processes will be described below. In the description below, the voltage at the “H” level corresponds to a logic of “1” and the voltage at the “L” level corresponds to a logic of “0.”

### 2.1 First Calculation Process

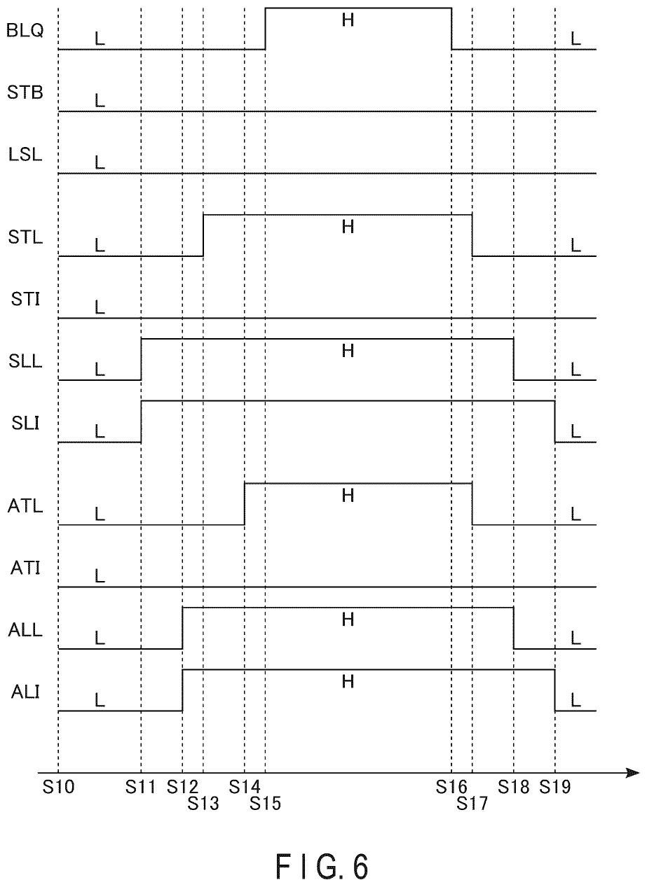

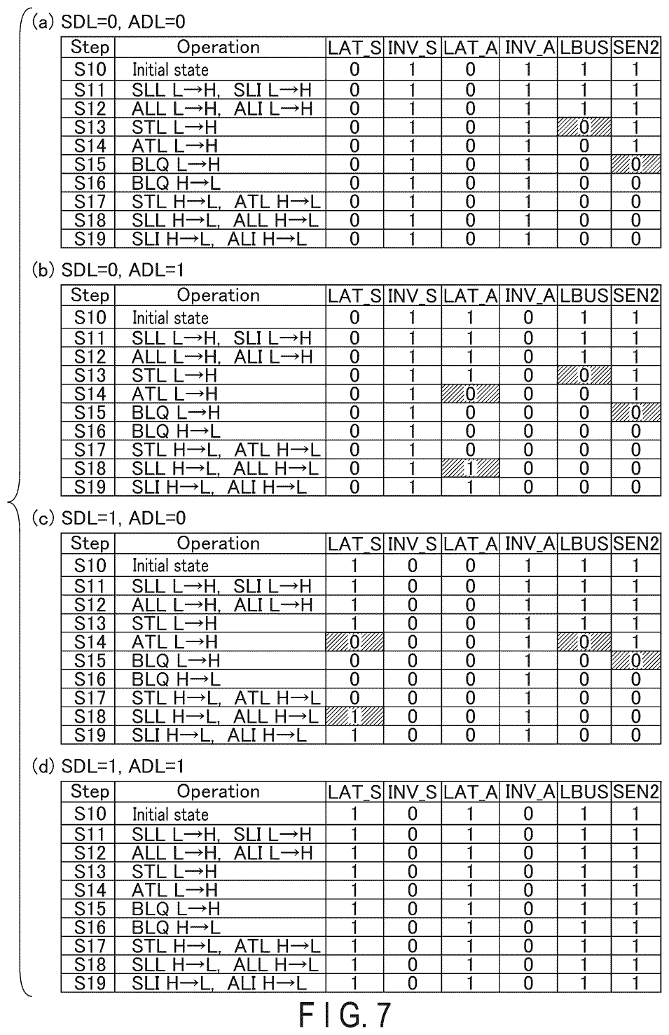

The first calculation process is a process in which an AND operation is performed on the data stored in a plurality of latch circuits and then the result is output to the node SEN2. In the description below, the first calculation process, in which the data stored in each of the latch circuits SDL and ADL is referenced and the operation result is output to the node SEN2, will be described with reference to FIG. 6 and FIG. 7.

FIG. 6 is a timing chart illustrating an example of the voltages of various signals during the first calculation process performed in the sense amplifier module of the semiconductor memory device according to the embodiment. FIG. 6 illustrates signals input to the circuit provided between the node SEN2 and the bus LBUS in the sense circuit SAC, and also illustrates signals input to the latch circuits SDL and ADL.

FIG. 7 is a table illustrating data held by each node and bus during the first calculation process performed in the sense amplifier module of the semiconductor memory device according to the embodiment. Table (a) in FIG. 7 illustrates the sequence of the first calculation process performed in a case where both the latch circuits SDL and ADL store “0” data. Table (b) illustrates the sequence of the first calculation process performed in a case where the latch circuit SDL stores “0” data and the latch circuit ADL stores “1” data. Table (c) illustrates the sequence of the first calculation process performed in a case where the latch circuit SDL stores “1” data and the latch circuit ADL stores “0” data. Table (d) illustrates the sequence of the first calculation process performed in a case where both the latch circuits SDL and ADL store “1” data. In FIG. 7, the notation “0” indicates that the node or bus has the “L” level signal (voltage), while the notation “1” indicates that the node or bus has the “H” level signal (voltage). In the tables of FIG. 7, the hatched columns indicate the parts where the logic has changed as a result of the calculation process in each step.

Step S10 in FIGS. 6 and 7 illustrates the initial state in each case. The latch circuits SDL and ADL store data corresponding to each case. The node SEN2 and the bus LBUS are precharged to the “H” level. The node SEN2 and the bus LBUS are precharged, for example, by setting control signals LPC and BLQ to the “H” level. After precharging, the control signals LPC and BLQ are set to the “L” level.

As illustrated in FIG. 6, the voltages of the control signals STB and LSL are at the “L” level throughout the first calculation process. That is, the transistors TR11 and TR14 are in the off state throughout the first calculation process.

In step S11, the voltages of the control signals SLL and SLI are set to the “H” level. Thus, the transistors TR27 and TR28 are set to the off state. That is, the inverters IV21 and IV22 are in the undriven state. The nodes LAT_S and INV_S are in a floating state while storing the respective levels of the initial state.

In step S12, the voltages of the control signals ALL and ALI are set to the “H” level. Thus, the transistors TR37 and TR38 are set to the off state. That is, the inverters IV31 and IV32 are in the undriven state. The nodes LAT_A and INV_A are in a floating state while storing the respective data in the initial state.

Steps S11 and S12 are executed with a certain time difference to adjust the execution timings of steps S13 and S14, for the suppression of overshoot to be described later.

Step S13 is executed a predetermined time after step S11. In step S13, the voltage of the control signal STL is set to the “H” level. Thus, the transistor TR21 is turned on. As a result, the data at the node LAT_S is read out to the bus LBUS. In the case where the node LAT_S stores “0” data (i.e., the latch circuit SDL stores “0” data) (FIG. 7, (a) and (b)), the transistor TR24 is in the on state, so that the voltage VSS_S1 is applied to the bus LBUS via the transistors TR21 and TR24. Therefore, the bus LBUS stores “0” data. In the case where the node LAT_S stores “1” data (i.e., the latch circuit SDL stores “1” data) (FIG. 7, (c) and (d)), the transistor TR24 is in the off state, so that the bus LBUS stores “1” data. It should be noted that step S13 may be executed at the same timing as step S12.

Step S14 is executed a predetermined time after step S12. In step S14, the voltage of the control signal ATL is set to the “H” level. Thus, the transistor TR31 is turned on. As a result, the data at the node LAT_A is read out to the bus LBUS. In the case where the node LAT_A stores “0” data (i.e., the latch circuit ADL stores “0” data) (FIG. 7, (a) and (c)), the transistor TR34 is in the on state, so that the voltage VSS_A1 is applied to the bus LBUS via the transistors TR31 and TR34. Therefore, the bus LBUS stores “0” data. In the case where the node LAT_S stores “1” data (FIG. 7, (c)), the voltage VSS_A1 is applied to the node LAT_S via the transistors TR21, TR31 and TR34 and the bus LBUS. Therefore, the node LAT_S stores “0” data. At this time, the node INV_S remains in a floating state, storing “0” data as its data. In the case where the node LAT_A stores “1” data (i.e., the latch circuit ADL stores “1” data) and the node LAT_S stores “0” data (FIG. 7, (b)), the voltage VSS_S1 is applied to the node LAT_A via the transistors TR21, TR24 and TR31 and the bus LBUS. Therefore, the node LAT_A and the bus LBUS store “0” data. At this time, the node INV_A remains in a floating state, storing “0” data as its data. In the case where the node LAT_A stores “1” data (i.e., the latch circuit ADL stores “1” data) and the node LAT_S stores “1” data (FIG. 7, (d)), the transistor TR34 is turned off, so that the bus LBUS stores “1” data.

Steps S13 and S14 are executed with a certain time difference between them. This is to suppress the phenomenon where the potential of the bus LBUS suddenly rises and overshoots, which occurs in a case where both the nodes LAT_S and LAT_A store “1” data (FIG. 7, (d)) and an “H” level voltage is simultaneously applied to the bus LBUS from both the latch circuits SDL and ADL.

In step S15, the voltage of the control signal BLQ is set to the “H” level. Thus, the transistor TR12 is turned on. Since the node SEN2 and the bus LBUS are electrically coupled, the node SEN2 stores data of the same logic as the data stored in the bus LBUS. It should be noted that step S15 may be executed at the same timing as step S14.

In step S16, the voltage of the control signal BLQ is set to the “L” level. This turns off the transistor TR12, and the node SEN2 and the bus LBUS are electrically decoupled from each other. The node SEN2 stores the result of an AND operation performed on the data stored in each of the latch circuits SDL and ADL.

The processes of steps S11 to S16 are referred to as an AND operation process. By the AND operation process, the result of the AND operation performed on the data stored in the latch circuits SDL and ADL can be output to the node SEN2.

In step S17, the voltages of the control signals STL and ATL are set to the “L” level. This causes the transistors TR21 and TR31 to be in the off state, and the latch circuits SDL and ADL and the bus LBUS are electrically decoupled from each other. It should be noted that step S17 may be executed at the same timing as step S16.

In step S18, the voltages of the control signals SLL and ALL are set to the “L” level. Thus, the transistors TR27 and TR37 are turned on. In other words, the inverters IV21 and IV31 are in the driving state. In the case where the data stored at the node LAT_S changes from “1” to “0” (FIG. 7, (c)), the transistor TR23 is in the on state since the node INV_S stores “0” data. Thus, the voltage VDDSA is applied to the node LAT_S via the transistors TR23 and TR27. Therefore, “1” data is written to the node LAT_S. In the case where the data stored at the node LAT_A changes from “1” to “0” (FIG. 7, (b)), the transistor TR33 is in the on state since the node INV_A stores “0” data. Thus, the voltage VDDSA is applied to the node LAT_A via the transistors TR33 and TR37. Therefore, “1” data is written to the node LAT_A.

In step S19, the voltages of the control signals SLI and ALI are set to the “L” level. Thus, the transistors TR28 and TR38 are turned on. In other words, the inverters IV22 and IV32 are in the driving state. As a result, the logic of the node LAT_S and the logic of the node INV_S, as well as the logic of the node LAT_A and the logic of the node INV_A, are each in an exclusive relationship. The latch circuit SDL stores the same data as the data stored at the node LAT_S. The latch circuit ADL stores the same data as the data stored at the node LAT_A.

The processes of steps S17 to S19 are referred to as a DL recovery process. The DL recovery process restores the data stored in each of the latch circuits SDL and ADL to the data stored in the initial state.

The calculation ends after step S19. As illustrated in FIG. 7, by the first calculation process, the result of the AND operation performed on the data stored in the latch circuits SDL and ADL can be output to the node SEN2, while the data stored in both circuits remains unchanged from their initial states (step S10).

The first calculation process is executed in the manner described above. In the example illustrated in FIG. 6 and FIG. 7, a similar process is performed when data stored in the latch circuits BDL, CDL, DDL, EDL and FDL are referenced instead of the data stored in the latch circuit SDL or ADL.

### 2.2 Second Calculation Process

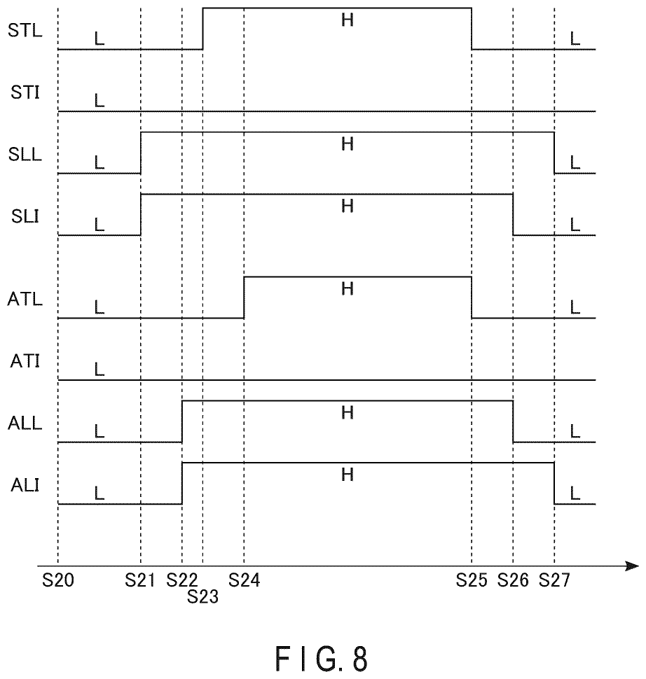

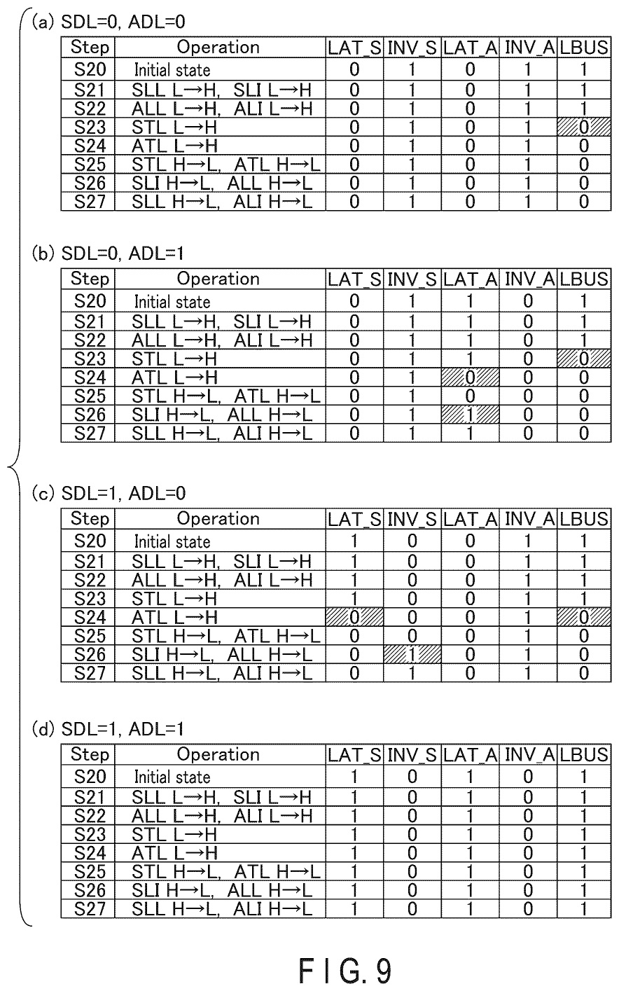

The second calculation process is a process in which an AND operation is performed by referencing data stored in a plurality of latch circuits and then the result is output to one of the referenced latch circuits as new storage data. In the description below, the second calculation process, in which the data stored in the latch circuits SDL and ADL is referenced and the operation result is output to the latch circuit SDL as new storage data, will be described with reference to FIG. 8 and FIG. 9.

FIG. 8 is a timing chart illustrating an example of the voltages of various signals during the second calculation process performed in the sense amplifier module of the semiconductor memory device according to the embodiment. FIG. 8 illustrates signals input to the latch circuits SDL and ADL.

FIG. 9 is a table illustrating the data held by each node and bus during the second calculation process performed in the sense amplifier module of the semiconductor memory device according to the embodiment. Table (a) in FIG. 9 illustrates the sequence of the second calculation process performed in a case where both the latch circuits SDL and ADL store “0” data. Table (b) illustrates the sequence of the second calculation process performed in a case where the latch circuit SDL stores “0” data and the latch circuit ADL stores “1” data. Table (c) illustrates the sequence of the second calculation process performed in the case the where the latch circuit SDL stores “1” data and the latch circuit ADL stores “0” data. Table (d) illustrates the sequence of the second calculation process performed in a case where both the latch circuits SDL and ADL store “1” data. In FIG. 9, the notation “0” indicates that the node or bus has an “L” level signal (voltage), while the notation “1” indicates that the node or bus has an “H” level signal (voltage). In the tables of FIG. 9, the hatched columns indicate the parts where the logic has changed as a result of the calculation process in each step.

Step S20 in FIGS. 8 and 9 illustrates the initial state in each case. The latch circuits SDL and ADL store data corresponding to each case. The bus LBUS is precharged to the “H” level. The bus LBUS is precharged, for example, by setting the control signal LPC to the “H” level. After precharging, the control signal LPC is set to the “L” level.

In steps S21 to S24, processes similar to those of steps S11 to S14 of the first calculation process illustrated in FIG. 6 and FIG. 7 are executed. As a result, the inverters IV21, IV22, IV31 and IV32 are in the undriven state, and the bus LBUS and the nodes LAT_S and LAT_A store the result of the AND operation performed on the data stored in the latch circuits SDL and ADL. The processes of steps S21 to S24 are referred to as an AND operation process.

In step S25, the voltages of the control signals STL and ATL are set to the “L” level. This causes the transistors TR21 and TR31 to be in the off state, and the latch circuits SDL and ADL and the bus LBUS are electrically decoupled from each other.

In step S26, the voltages of the control signals SLI and ALL are set to the “L” level. Thus, the transistors TR28 and TR37 are turned on. In other words, the inverters IV22 and IV31 are in the driving state. In the case where the data stored at the node LAT_S changes from “1” to “0” (FIG. 9(c)), the transistor TR25 is in the on state. Thus, the voltage VDDSA is applied to the node INV_S via the transistors TR25 and TR28. Therefore, “1” data is written to the node INV_S. In the case where the data stored at the node LAT_A changes from “1” to “0” (FIG. 9(b)), the voltage VDDSA is applied to the node LAT_A via the transistors TR33 and TR37 since the node INV_A stores “0” data and the transistor TR33 is in the on state. Therefore, “1” data is written to the node LAT_A.

In step S27, the voltages of the control signals SLL and ALI are set to the “L” level. Thus, the transistors TR27 and TR38 are turned on. In other words, the inverters IV21 and IV32 are in the driving state. As a result, the logic of the node LAT_S and the logic of the node INV_S, as well as the logic of the node LAT_A and the logic of the node INV_A, are each in an exclusive relationship. The latch circuit SDL stores the same data as the data stored at the node LAT_S. The latch circuit ADL stores the same data as the data stored at the node LAT_A.

The processes of steps S25 to S27 are referred to as a DL recovery process. As a result of the DL recovery process, the data stored in the latch circuit SDL is updated to the result of the AND operation process, and the data stored in the latch circuit ADL is restored to the data stored in the initial state.

The calculation ends after step S27. As illustrated in FIG. 9, by the second calculation process, the result of the AND operation performed on the data stored in the latch circuits SDL and ADL can be stored in the latch circuit SDL as new storage data, while the data stored in the latch circuit ADL remains unchanged from its initial state (step S20).

The second calculation process is executed in the manner described above. In the example illustrated in FIG. 8 and FIG. 9, a similar process is performed when data stored in the latch circuits BDL, CDL, DDL, EDL and FDL are referenced instead of the data stored in the latch circuit SDL or ADL.

### 2.3 Third Calculation Process

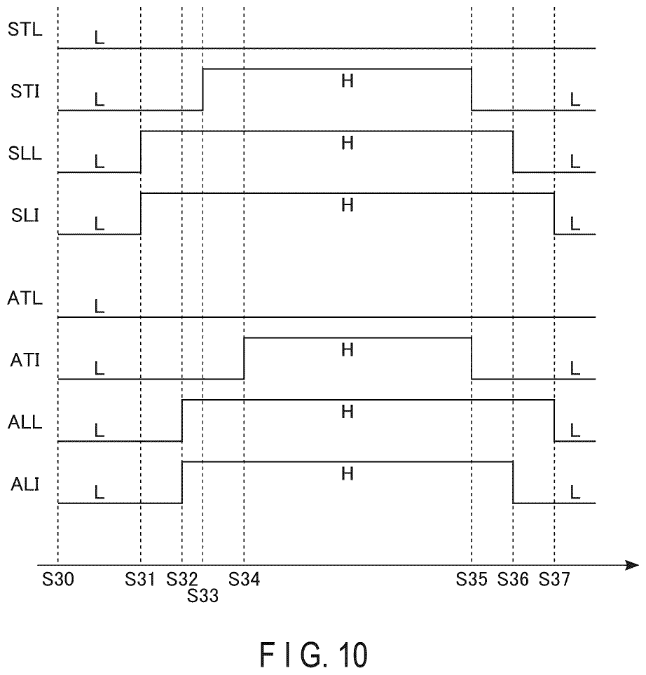

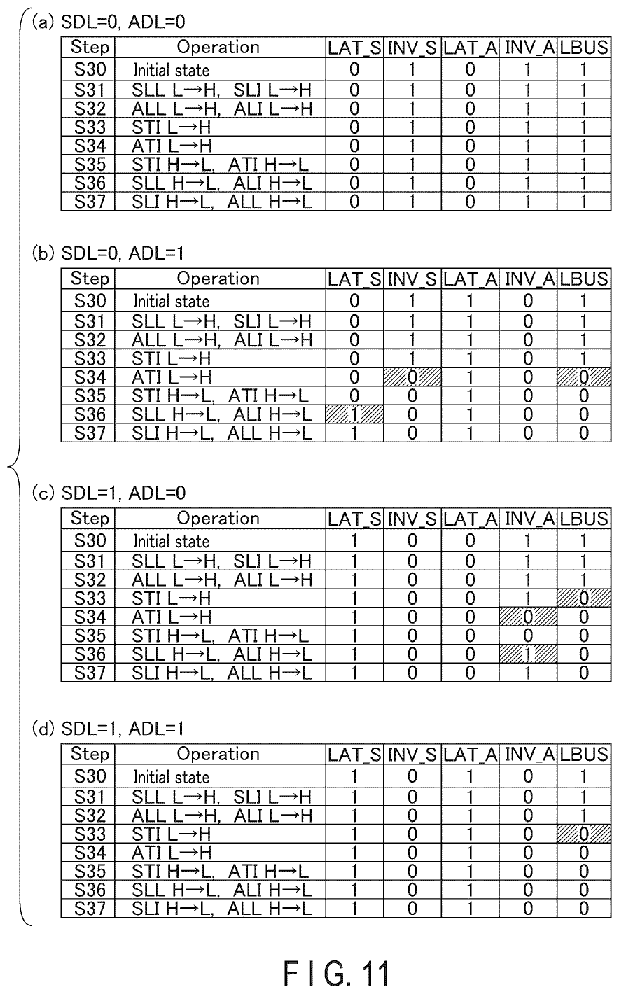

The third calculation process is a process in which an OR operation is performed by referencing data stored in a plurality of latch circuits and then the result is output to one of the referenced latch circuits as new storage data. In the description below, the third calculation process, in which the data stored in the latch circuits SDL and ADL is referenced and the operation result is output to the latch circuit SDL as new storage data, will be described with reference to FIG. 10 and FIG. 11.

FIG. 10 is a timing chart illustrating an example of the voltages of various signals during the third calculation process performed in the sense amplifier module of the semiconductor memory device according to the embodiment. FIG. 10 illustrates signals input to the latch circuits SDL and ADL.

FIG. 11 is a table illustrating the data held by each node and bus during the third calculation process performed in the sense amplifier module of the semiconductor memory device according to the embodiment. Table (a) in FIG. 11 illustrates the sequence of the third calculation process performed in a case where both the latch circuits SDL and ADL store “0” data. Table (b) illustrates the sequence of the third calculation process performed in a case where the latch circuit SDL stores “0” data and the latch circuit ADL stores “1” data. Table (c) illustrates the sequence of the third calculation process performed in a case where the latch circuit SDL stores “1” data and the latch circuit ADL stores “0” data. Table (d) illustrates the sequence of the third calculation process performed in a case where both the latch circuits SDL and ADL store “1” data. In FIG. 11, the notation “0” indicates that the node or bus has an “L” level signal (voltage), while the notation “1” indicates that the node or bus has an “H” level signal (voltage). In the tables in FIG. 11, the hatched columns indicate the parts where the logic has changed as a result of the calculation process in each step.

Step S30 in FIGS. 10 and 11 illustrates the initial state in each case. The latch circuits SDL and ADL store data corresponding to each case. The bus LBUS is precharged to the “H” level. The bus LBUS is precharged, for example, by setting the control signal LPC to the “H” level. After precharging, the control signal LPC is set to the “L” level.

In step S31, the voltages of the control signals SLL and SLI are set to the “H” level. Thus, the transistors TR27 and TR28 are set to the off state. That is, the inverters IV21 and IV22 are in the undriven state. The nodes LAT_S and INV_S are in a floating state while storing the respective levels of the initial state.

In step S32, the voltages of the control signals ALL and ALI are set to the “H” level. As a result, the transistors TR37 and TR38 are set to the off state. That is, the inverters IV31 and IV32 are in the undriven state. The nodes LAT_A and INV_A are in a floating state while storing the respective data in the initial state.

Steps S31 and S32 are executed with a certain time difference to adjust the execution timings of steps S33 and S34, for the suppression of overshoot to be described later.

Step S33 is executed a predetermined time after step S31. In step S33, the voltage of the control signal ST1 is set to the “H” level. Thus, the transistor TR22 is turned on. As a result, the data at the node INV_S is read out to the bus LBUS. In the case where the node INV_S stores “1” data (i.e., the latch circuit SDL stores “0” data) (FIG. 11, (a) and (b)), the transistor TR26 is in the off state and the bus LBUS stores “1” data. In the case where the node INV_S stores “0” data (i.e., the latch circuit SDL stores “1” data) (FIG. 11, (c) and (d)), the transistor TR26 is in the on state and the voltage VSS_S2 is applied to the bus LBUS via the transistors TR22 and TR26. Therefore, the bus LBUS stores “0” data. It should be noted that step S33 may be executed at the same timing as step S32.

Step S34 is executed a predetermined time after step S32. In step S34, the voltage of the control signal ATI is set to the “H” level. Thus, the transistor TR32 is turned on. As a result, the data at the node INV_A is read out to the bus LBUS. In the case where the node INV_A stores “1” data (i.e., the latch circuit ADL stores “0” data) and the node INV_S stores “1” data (FIG. 11, (a)), the transistor TR36 is turned off, and the bus LBUS stores “1” data. In the case where the node INV_A stores “1” data (i.e., the latch circuit ADL stores “0” data) and the node INV_S stores “0” data (FIG. 11, (c)), the voltage VSS_S2 is applied to the node INV_A via the transistors TR22, TR26 and TR32 and the bus LBUS. Therefore, the node INV_A and the bus LBUS store “0” data. At this time, the node LAT_A remains in a floating state, storing “0” data as its data. In the case where the node INV_A stores “0” data (i.e., the latch circuit ADL stores “1” data) (FIG. 11, (b) and (d)), the transistor TR36 is in the on state, and the voltage VSS_A2 is applied to the bus LBUS via the transistors TR32 and TR36. Therefore, the bus LBUS stores “0” data. In the case where the node INV_S stores “1” data (FIG. 11, (b)), the voltage VSS_A2 is applied to the node INV_S via the transistors TR22, TR32 and TR36 and the bus LBUS. Therefore, the node INV_S stores “0” data. At this time, the node LAT_S remains in a floating state, storing “0” data as its data.

Steps S33 and S34 are executed with a certain time difference. This is to suppress the phenomenon where the potential of the bus LBUS suddenly rises and overshoots, which occurs in a case where both the nodes INV_S and INV_A store “1” data (FIG. 11, (a)) and an “H” level voltage is simultaneously applied to the bus LBUS from both the latch circuits SDL and ADL.

The processes of steps S31 to S34 are referred to as an OR operation process. By the OR operation process, the inverted logic of the OR operation result of the data stored in the latch circuits SDL and ADL is stored on the bus LBUS and at the nodes INV_S and INV_A. It should be noted that the OR operation process reads out the inverted logic of the data stored in the latch circuit SDL and the inverted logic of the data stored in the latch circuit ADL and performs an AND operation on the bus LBUS, so that the OR operation process can be considered to be a NAND operation that is performed on the bus LBUS on the data stored in the latch circuits SDL and ADL.

In step S35, the voltages of the control signals STI and ATI are set to the “L” level. This causes the transistors TR22 and TR32 to be in the off state, and the latch circuits SDL and ADL and the bus LBUS are electrically decoupled from each other.

In step S36, the voltages of the control signals SLL and ALI are set to the “L” level. Thus, the transistors TR27 and TR38 are turned on. In other words, the inverters IV21 and IV32 are in the driving state. In the case where the data stored at the node INV_S changes from “1” to “0” (FIG. 11, (b)), the transistor TR23 is in the on state. Thus, the voltage VDDSA is applied to the node LAT_S via the transistors TR23 and TR27. Therefore, “1” data is written to the node LAT_S. In the case where the data stored at the node INV_A changes from “1” to “0” (FIG. 11, (c)), the voltage VDDSA is applied to the node INV_A via the transistors TR35 and TR38 since the node LAT_A stores “0” data and the transistor TR35 is in the on state. Therefore, “1” data is written to the node LAT_A.

In step S37, the voltages of the control signals SLI and ALL are set to the “L” level. Thus, the transistors TR28 and TR37 are turned on. In other words, the inverters IV22 and IV31 are in the driving state. As a result, the logic of the node LAT_S and the logic of the node INV_S, as well as the logic of the node LAT_A and the logic of the node INV_A, are each in an exclusive relationship. The latch circuit SDL stores the same data as the data stored at the node LAT_S. The latch circuit ADL stores the same data as the data stored at the node LAT_A.

The processes of steps S35 to S37 are referred to as a DL recovery process. As a result of the DL recovery process, the data stored in the latch circuit SDL is updated to the result of the OR operation process, and the data stored in the latch circuit ADL is restored to the data stored in the initial state. It should be noted that the latch circuit SDL can be considered to store inverted data of the result of the NAND operation stored in the bus LBUS.

The calculation ends after step S37. As illustrated in FIG. 11, by the third calculation process, the result of the OR operation performed on the data stored in the latch circuits SDL and ADL can be stored in the latch circuit SDL as new storage data, while the data stored in the latch circuit ADL remains unchanged from its initial state (step S30).

The third calculation process is executed in the manner described above. In the example illustrated in FIG. 10 and FIG. 11, a similar process is performed when data stored in the latch circuits BDL, CDL, DDL, EDL and FDL are referenced instead of the data stored in the latch circuit SDL or ADL.

### 3. Advantages

The operation method according to the present embodiment can shorten the processing time required to write data to a memory cell. This advantage will be described in detail below.

According to the present embodiment, in the first to third calculation processes, each of the latch circuits SDL, ADL, BDL, CDL, DDL, EDL and FDL sets its inverters in an undriven state. For example, in the first to third calculation processes, the latch circuit SDL sets its inverters IV21 and IV22 in an undriven state. The voltage levels of the nodes LAT_S and INV_S are therefore stored in a floating state. Thus, even if the voltage level of either node LAT_S or INV_S changes due to the AND or OR operation processes in the first to third calculation processes, the initial voltage level can be restored (DL recovery) by referencing the voltage level of the other node. Similarly, the latch circuits ADL, BDL, CDL, DDL, EDL and FDL can also perform DL recovery.

Therefore, during the first to third calculation processes in which a plurality pieces of data in one of the plurality of latch circuits SDL, ADL, BDL, CDL, DDL, EDL and FDL are referenced, the sense amplifier module 17 can simultaneously access the plurality of latch circuits and perform batch calculation operations.

Specifically, for instance, when the first calculation process referencing data stored in the plurality of latch circuits is executed, the bus LBUS is precharged only once, regardless of the number of latch circuits referenced. In addition, the data exchange between the bus LBUS and the node SEN2 is executed only once, regardless of the number of latch circuits referenced. Therefore, compared with a configuration in which data is read for each latch circuit and transmitted to the node SEN2 one by one to perform an AND operation, the number of times the bus LBUS is precharged and the number of times data is exchanged between the bus LBUS and the node SEN2 can be reduced. Hence, the processing time required for the AND operation can be shortened.

For example, when the second or third calculation process referencing data stored in a plurality of latch circuits is performed, the bus LBUS is precharged only once, regardless of the number of latch circuits referenced. Furthermore, data exchange between the bus LBUS and the latch circuit storing the calculation result is performed only once, regardless of the number of latch circuits referenced. Therefore, compared with a configuration in which data is read for each latch circuit and transmitted one by one to the latch circuit that stores the operation result to perform an AND or OR operation, the number of times the bus LBUS is precharged and the number of times data is exchanged between the bus LBUS and the latch circuit storing the calculation result can be reduced. Hence, the processing time required for the AND and OR operations can be shortened.

Furthermore, since the bus LBUS is precharged only once during the execution of the first calculation process, the phenomenon where the voltage of the node SEN2 rises due to subsequent precharges of the bus LBUS does not occur. Thus, it becomes possible to omit a configuration in which the voltage of the control signal BLQ is reduced below the other power supply voltage VCC to prevent a voltage rise at the node SEN2. Hence, the sense amplifier module 17 can be easily configured during the manufacturing process.

In the sense amplifier module 17 included in the semiconductor memory device 3 according to the present embodiment, the latch circuits SDL, ADL, BDL, CDL, DDL, EDL and FDL do not share a node that supplies an “L” level voltage. In addition, even within one latch circuit, the node that supplies an “L” level voltage is not shared. Specifically, for example, in the latch circuit SDL, the node to which the voltage VSS_S1 is applied is not coupled to the node to which the voltage VSS_S2 is applied, the node to which the voltage VSS_A1 is applied, or the node to which the voltage VSS_A2 is applied. With this configuration, for example, when the charge at the node LAT_S is discharged through the node with the voltage VSS_S1 applied, changes in the stored logic level caused by the discharged charge flowing back to the other nodes such as the nodes INV_S, LAT_A, or INV_A can be suppressed. Consequently, the reliability of the semiconductor memory device 3 can be improved.

### 4. Extension

In the above embodiment, a description was given of a calculation process that references data stored in two latch circuits among the plurality of latch circuits included in the sense amplifier module 17. However, this can be extended to calculation processes that reference data stored in three or more latch circuits. As an example, a first calculation process, a second calculation process, and a third calculation process that reference the data stored in three latch circuits SDL, ADL and BDL will be described below.

As illustrated in FIG. 5, the latch circuit BDL has a configuration similar to that of the latch circuits SDL and ADL. The node LAT_B corresponds to the node LAT_S of the latch circuit SDL and the node LAT_A of the latch circuit ADL. The node INV_B corresponds to the node INV_S of the latch circuit SDL and the node INV_A of the latch circuit ADL. The control signals BTL, BTI, BLL and BLI correspond to the control signals STL, STI, SLL and SLI in the latch circuit SDL, respectively. The voltages VSS_B1 and VSS B2 are, for example, the ground voltage VSS.

### 4.1 First Calculation Process

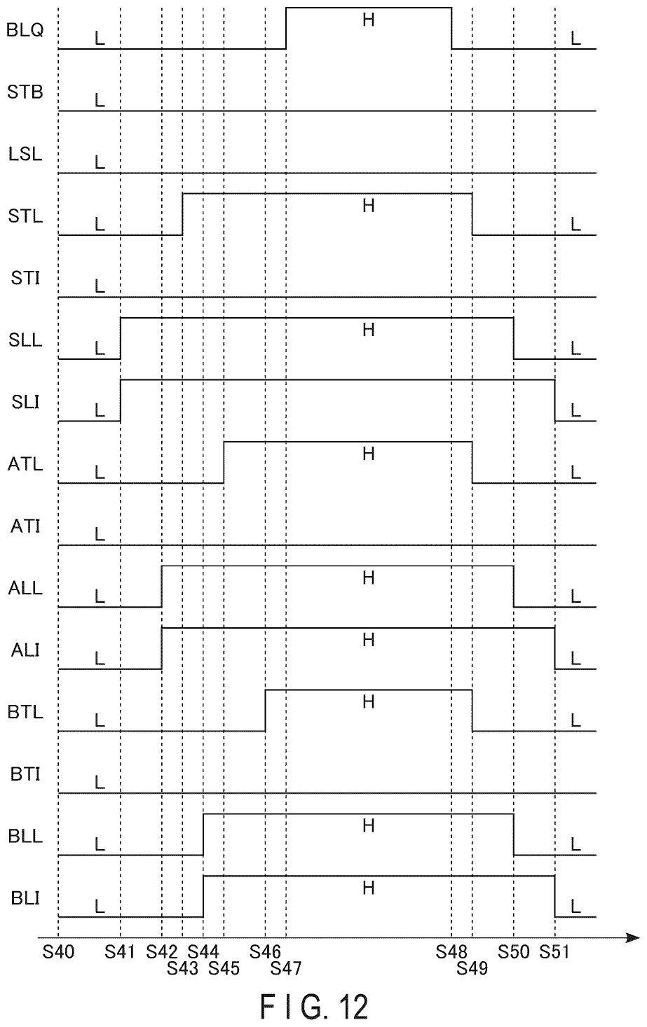

A first calculation process will be described in which an AND operation is performed on the data stored in each of the latch circuits SDL, ADL and BDL, and the operation result is output to the node SEN2. FIG. 12 is a timing chart illustrating an example of the voltages of various signals during the first calculation process performed in the sense amplifier module of the semiconductor memory device according to the embodiment.

Step S40 in FIG. 12 illustrates the initial state before the first calculation process is executed. The latch circuits SDL, ADL and BDL each store arbitrary data. The node SEN2 and the bus LBUS are precharged to the “H” level. The node SEN2 and the bus LBUS are precharged, for example, by setting control signals LPC and BLQ to the “H” level. After precharging, the control signals LPC and BLQ are set to the “L” level.

As illustrated in FIG. 12, the voltages of the control signals STB and LSL are at the “L” level throughout the first calculation process.

In step S41, the voltages of the control signals SLL and SLI are set to the “H” level. Thus, the nodes LAT_S and INV_S are in a floating state while storing the respective levels of the initial state.

In step S42, the voltages of the control signals ALL and ALI are set to the “H” level. Thus, the nodes LAT_A and INV_A are in a floating state while storing the respective data in the initial state.

Step S43 is executed a predetermined time after step S41. In step S43, the voltage of the control signal STL is set to the “H” level. Thus, the data at the node LAT_S is read out to the bus LBUS. It should be noted that step S43 may be executed at the same timing as step S42.

In step S44, the voltages of the control signals BLL and BLI are set to the “H” level. Thus, the nodes LAT_B and INV_B are in a floating state while storing the respective data in the initial state.

Steps S41, S42 and S44 are executed with a certain time difference to adjust the execution timings of steps S43, S45 and S46, for the suppression of overshoot to be described later.

Step S45 is executed a predetermined time after step S42. In step S45, the voltage of the control signal ATL is set to the “H” level. Thus, the data at the node LAT_A is read out to the bus LBUS. At this time, on the bus LBUS, an AND operation is performed on the data stored at the node LAT_S (i.e., the data stored in the latch circuit SDL) and the data stored at the node LAT_A (i.e., the data stored in the latch circuit ADL). It should be noted that step S45 may be executed at the same timing as step S44.

Step S46 is executed a predetermined time after step S44. In step S46, the voltage of the control signal BTL is set to the “H” level. Thus, the data at the node LAT_B is read out to the bus LBUS. At this time, on the bus LBUS, an AND operation is performed on the result of the AND operation performed in step S45 and the data stored at the node LAT_B (i.e., the data stored in the latch circuit BDL). Thus, the result of the AND operation performed on the data stored in each of the latch circuits SDL, ADL and BDL is stored in the bus LBUS and the nodes LAT_S, LAT_A and LAT_B.

Steps S43, S45 and S46 are executed with a certain time difference between them. This is to prevent the potential of the bus LBUS from suddenly increasing and overshooting.

In step S47, the voltage of the control signal BLQ is set to the “H” level. Since the node SEN2 and the bus LBUS are electrically coupled, the node SEN2 stores data of the same logic as the data stored in the bus LBUS. It should be noted that step S47 may be executed at the same timing as step S46.

In step S48, the voltage of the control signal BLQ is set to the “L” level. This electrically decouples the node SEN2 from the bus LBUS. The result of the first calculation process is stored at the node SEN2.

The processes of steps S41 to S48 are referred to as an AND operation process. By the AND operation process, the result of the AND operation performed on the data stored in the latch circuits SDL, ADL and BDL can be output to the node SEN2.

In step S49, the voltages of the control signals STL, ATL and BTL are set to the “L” level. This causes the latch circuits SDL, ADL and BDL and the bus LBUS to be electrically decoupled from each other. It should be noted that step S49 may be executed at the same timing as step S48.

In step S50, the voltages of the control signals SLL, ALL and BLL are set to the “L” level. Thus, data of the initial state is written to each of the nodes LAT_S, LAT_A and LAT_B. Therefore, if the level of each of the nodes LAT_S, LAT_A and LAT_B changes from before the calculation, it is restored to the level of the initial state.

In step S51, the voltages of the control signals SLI, ALI and BLI are set to the “L” level. Thus, the logic of the node LAT_S and the logic of the node INV_S, the logic of the node LAT_A and the logic of the node INV_A, and the logic of the node LAT_B and the logic of the node INV_B are each in an exclusive relationship. The latch circuit SDL stores the same data as the data stored at the node LAT_S. The latch circuit ADL stores the same data as the data stored at the node LAT_A. The latch circuit BDL stores the same data as the data stored at the node LAT_B.

The processes of steps S49 to S51 are referred to as a DL recovery process. The DL recovery process restores the data stored in each of the latch circuits SDL, ADL and BDL to the data stored in the initial state.

The calculation ends after step S51. By the first calculation process, the result of the AND operation performed on the data stored in the latch circuits SDL, ADL and BDL can be output to the node SEN2, while the data stored in the latch circuits SDL, ADL and BDL remains unchanged from their initial states (step S40).

The first calculation process is executed in the manner described above. In the example illustrated in FIG. 12, a similar process is performed when data stored in the latch circuits CDL, DDL, EDL and FDL are referenced instead of the data stored in the latch circuit SDL, ADL or BDL. Furthermore, even in a case where the number of latch circuits holding referenced data is four or more, the latch circuits are sequentially coupled to the bus LBUS to perform an AND operation, and after being decoupled from the bus LBUS, the DL recovery process is performed individually, thereby obtaining a similar operation result and storing it at the node SEN2. The latch circuits are returned to their initial states.

### 4.2 Second Calculation Process

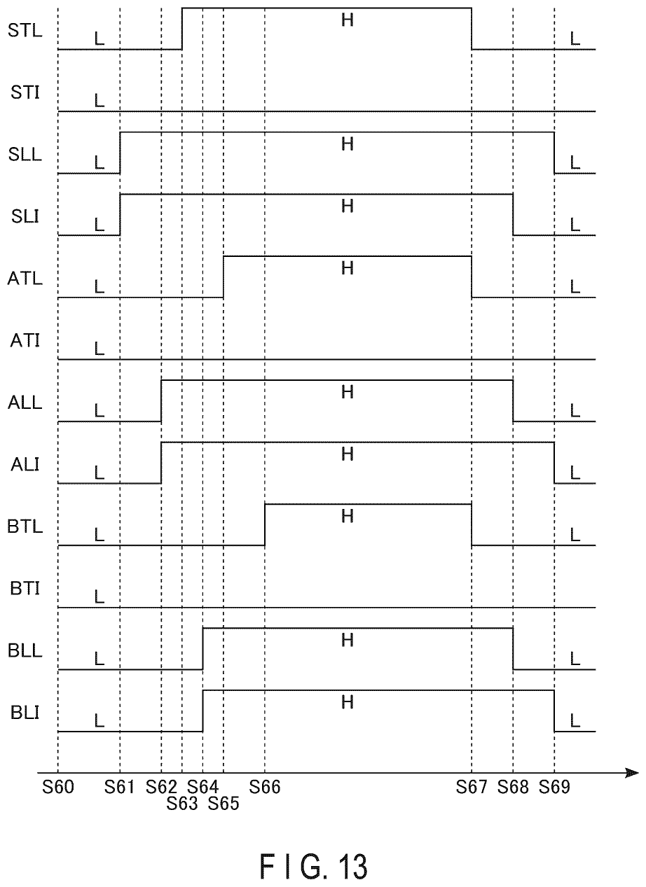

A second calculation process will be described in which an AND operation is performed on the data stored in each of the latch circuits SDL, ADL and BDL, and the operation result is output to the latch circuit SDL. FIG. 13 is a timing chart illustrating an example of the voltages of various signals during the second calculation process performed in the sense amplifier module of the semiconductor memory device according to the embodiment.

Step S60 in FIG. 13 illustrates the initial state before the second calculation process is executed. The latch circuits SDL, ADL and BDL each store arbitrary data. The bus LBUS is precharged to the “H” level. The bus LBUS is precharged, for example, by setting the control signal LPC to the “H” level. After precharging, the control signal LPC is set to the “L” level.

With respect to steps S61 to S66, processes similar to those of steps S41 to S46 of the first calculation process illustrated in FIG. 12 are executed. Thus, the results of the AND operation performed on the data stored in the latch circuits SDL, ADL and BDL are stored in the bus LBUS and the nodes LAT_S, LAT_A and LAT_B. The processes of steps S61 to S66 are referred to as an AND operation process.

In step S67, the voltages of the control signals STL, ATL and BTL are set to the “L” level. This causes the latch circuits SDL, ADL and BDL and the bus LBUS to be electrically decoupled from each other.

In step S68, the voltages of the control signals SLI, ALL and BLL are set to the “L” level. Thus, in the latch circuit SDL, data indicating the inverted logic of the data at the node LAT_S (i.e., the result of the AND operation) is written to the node INV_S. In the latch circuits ADL and BDL, the data of their respective initial states is written to the LAT_A and LAT_B. Therefore, if the level of each of the nodes LAT_A and LAT_B changes from before the calculation, it is restored to the level of the initial state.

In step S69, the voltages of the control signals SLL, ALI and BLI are set to the “L” level. Thus, the logic of the node LAT_S and the logic of the node INV_S, the logic of the node LAT_A and the logic of the node INV_A, and the logic of the node LAT_B and the logic of the node INV_B are each in an exclusive relationship. The latch circuit SDL stores the same data as the data stored at the node LAT_S. The latch circuit ADL stores the same data as the data stored at the node LAT_A. The latch circuit BDL stores the same data as the data stored at the node LAT_B.

The processes of steps S67 to S69 are referred to as a DL recovery process. As a result of the DL recovery process, the data stored in the latch circuit SDL is updated to the result of the AND operation process, and the data stored in the latch circuits ADL and BDL is restored to the data stored in their initial states.

The calculation ends after step S69. By the second calculation process, the result of the AND operation performed on the data stored in the latch circuits SDL, ADL and BDL can be stored in the latch circuit SDL as new storage data, while the data stored in the latch circuits ADL and BDL remains unchanged from their initial states (step S60).

The second calculation process is executed in the manner described above. In the example illustrated in FIG. 13, a similar process is performed when data stored in the latch circuits CDL, DDL, EDL and FDL are referenced instead of the data stored in the latch circuit SDL, ADL or BDL. Furthermore, even in a case where the number of latch circuits holding referenced data is four or more, the latch circuits are sequentially coupled to the bus LBUS to perform an AND operation, and after being decoupled from the bus LBUS, the DL recovery process is performed individually, thereby obtaining a similar operation result and storing it in the targeted latch circuit. The referenced latch circuits are returned to their initial states.

### 4.3 Third Calculation Process

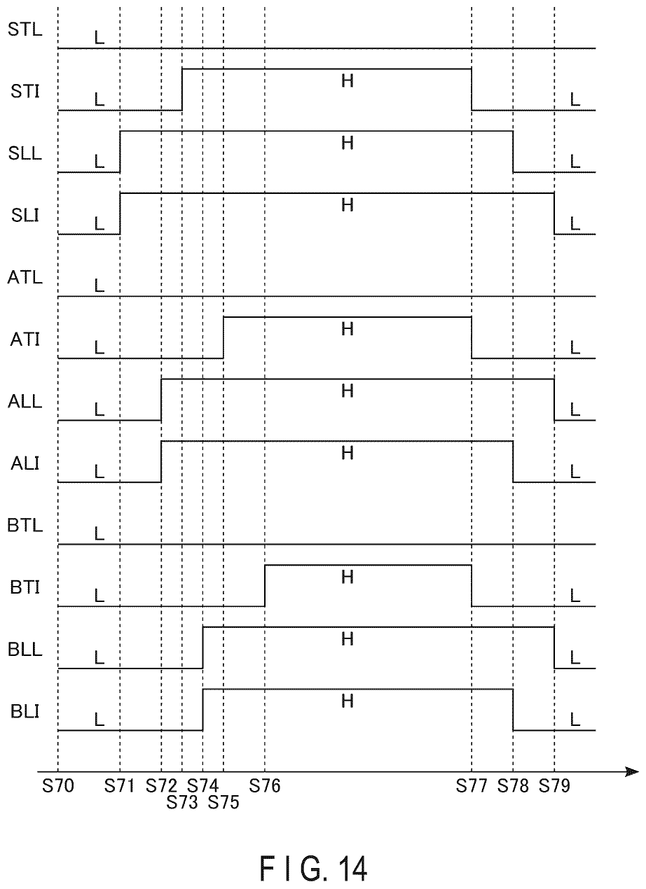

A third calculation process will be described in which an OR operation is performed on the data stored in each of the latch circuits SDL, ADL and BDL, and the operation result is output to the latch circuit SDL. FIG. 14 is a timing chart illustrating an example of the voltages of various signals during the third calculation process performed in the sense amplifier module of the semiconductor memory device according to the embodiment.

Step S70 in FIG. 14 illustrates the initial state before the third calculation process is executed. The latch circuits SDL, ADL and BDL each store arbitrary data. The bus LBUS is precharged to the “H” level. The bus LBUS is precharged, for example, by setting the control signal LPC to the “H” level. After precharging, the control signal LPC is set to the “L” level.

In step S71, the voltages of the control signals SLL and SLI are set to the “H” level. Thus, the nodes LAT_S and INV_S are in a floating state while storing the respective levels of the initial state.

In step S72, the voltages of the control signals ALL and ALI are set to the “H” level. Thus, the nodes LAT_A and INV_A are in a floating state while storing the respective data in the initial state.

Step S73 is executed a predetermined time after step S71. In step S73, the voltage of the control signal ST1 is set to the “H” level. Thus, the data at the node INV_S is read out to the bus LBUS. It should be noted that step S73 may be executed at the same timing as step S72.

In step S74, the voltages of the control signals BLL and BLI are set to the “H” level. Thus, the nodes LAT_B and INV_B are in a floating state while storing the respective data in the initial state.

Steps S71, S72 and S74 are executed with a certain time difference to adjust the execution timings of steps S73, S75 and S76, for the suppression of overshoot to be described later.

Step S75 is executed a predetermined time after step S72. In step S75, the voltage of the control signal ATI is set to the “H” level. Thus, the data at the node INV_A is read out to the bus LBUS. At this time, on the bus LBUS, an AND operation is executed on the data stored at the node INV_S (i.e., the data having the inverted logic of the data stored in the latch circuit SDL) and the data stored at the node INV_A (i.e., the data having the inverted logic of the data stored in the latch circuit ADL). It should be noted that step S75 may be executed at the same timing as step S74.

Step S76 is executed a predetermined time after step S74. In step S76, the voltage of the control signal BTI is set to the “H” level. Thus, the data at the node INV_B is read out to the bus LBUS. At this time, on the bus LBUS, an AND operation is performed on the result of the AND operation performed in step S75 and the data stored at the node INV_B (i.e., the data having the inverted logic of the data stored in the latch circuit BDL).

Steps S73, S75 and S76 are executed with a certain time difference between them. This is to prevent the potential of the bus LBUS from suddenly increasing and overshooting.

The processes of steps S71 to S76 are referred to as an OR operation process. By the OR operation process, the inverted logic of the OR operation result of the data stored in the latch circuits SDL, ADL and BDL is stored on the bus LBUS and on the node INV_S. It should be noted that the OR operation process reads out the inverted logic of the data stored in the latch circuits SDL, ADL and BDL, and performs an AND operation on the bus LBUS. Consequently, the OR operation can be regarded as equivalent to a NAND operation performed on the bus LBUS on the data stored in the latch circuits SDL, ADL and BDL.

In step S77, the voltages of the control signals STI, ATI and BTI are set to the “L” level. This causes the latch circuits SDL, ADL and BDL and the bus LBUS to be electrically decoupled from each other.

In step S78, the voltages of the control signals SLL, ALI and BLI are set to the “L” level. Thus, in the latch circuit SDL, data indicating the inverted logic of the data at the node INV_S (i.e., the result of the OR operation) is written to the node LAT_S. Therefore, the result of the OR operation is stored in the latch circuit SDL. In the latch circuits ADL and BDL, data of the respective initial states is written to the INV_A and INV_B. Therefore, if the level of each of the nodes INV_A and INV_B changes from before the calculation, it is restored to the level of the initial state.

In step S79, the voltages of the control signals SLI, ALL and BLL are set to the “L” level. Thus, the logic of the node LAT_S and the logic of the node INV_S, the logic of the node LAT_A and the logic of the node INV_A, and the logic of the node LAT_B and the logic of the node INV_B are each in an exclusive relationship. The latch circuit SDL stores the same data as the data stored at the node LAT_S. The latch circuit ADL stores the same data as the data stored at the node LAT_A. The latch circuit BDL stores the same data as the data stored at the node LAT_B.

The processes of steps S77 to S79 are referred to as a DL recovery process. As a result of the DL recovery process, the data stored in the latch circuit SDL is updated to the result of the OR operation process, and the data stored in the latch circuits ADL and BDL is restored to the data stored in their initial states. It should be noted that the latch circuit SDL can be considered to store inverted data of the result of the NAND operation stored in the bus LBUS.

The calculation ends after step S79. By the third calculation process, the result of the OR operation performed on the data stored in the latch circuits SDL, ADL and BDL can be stored in the latch circuit SDL as new storage data, while the data stored in each of the latch circuits ADL and BDL remains unchanged from their initial states (step S70).

The third calculation process is executed in the manner described above. In the example illustrated in FIG. 14, a similar process is performed when data stored in the latch circuits CDL, DDL, EDL and FDL are referenced instead of the data stored in the latch circuit SDL, ADL or BDL. Furthermore, even in a case where the number of latch circuits holding referenced data is four or more, the latch circuits are sequentially coupled to the bus LBUS to perform an OR operation, and after being decoupled from the bus LBUS, the DL recovery process is performed individually, thereby obtaining a similar operation result and storing it in the targeted latch circuit. The referenced latch circuits are returned to their initial states.

### 5. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An operation method using a first latch circuit including: a first inverter that includes an input terminal coupled to a first node and an output terminal coupled to a second node; and a second inverter that includes an input terminal coupled to the second node and an output terminal coupled to the first node,
the operation method comprising:
storing first data in the first node and second data, which is inverted data of the first data, in the second node by setting the first inverter and the second inverter to a driven state;
reading the first data from the first node to a bus coupled to the first latch circuit by setting the first inverter and the second inverter to an undriven state;
writing the first data based on the second data to the first node from which the first data is read by setting the first inverter to the driven state; and
driving the second inverter after the first data is written.

2. The operation method according to claim 1, further using a second latch circuit including: a third inverter that includes an input terminal coupled to a third node and an output terminal coupled to a fourth node; and a fourth inverter that includes an input terminal coupled to the fourth node and an output terminal coupled to the third node, wherein
the storing further includes storing third data in the third node and fourth data, which is inverted data of the third data, in the fourth node by setting the third inverter and the fourth inverter to the driven state,
the reading further includes reading the third data from the third node to the bus by setting the third inverter and the fourth inverter to the undriven state.

3. The operation method according to claim 2, further comprising:
performing an AND operation on the first data and the third data read out to the bus, and outputting fifth data that is a result of the AND operation.

4. The operation method according to claim 3, wherein the outputting includes outputting the fifth data to a sense circuit coupled to the bus.

5. The operation method according to claim 2, wherein
the writing further includes writing the third data based on the fourth data to the third node from which the third data is read by setting the third inverter to the driven state, and
the driving further includes driving the fourth inverter after the third data is written.

6. The operation method according to claim 3, wherein the outputting includes outputting the fifth data to the third node.

7. The operation method according to claim 6, wherein
the writing further includes writing sixth data, which is inverted data of the fifth data, to the fourth node by setting the fourth inverter to driven state after the fifth data is output to the third node, and
the driving further includes driving the third inverter after the sixth data is written.

8. A semiconductor memory device comprising:
a sequencer;
a sense circuit;
a bus coupled to the sense circuit; and
a first latch circuit including: a first inverter that includes an input terminal coupled to a first node coupled to the bus and an output terminal coupled to a second node coupled to the bus; and a second inverter that includes an input terminal coupled to the second node and an output terminal coupled to the first node; wherein
the sequencer is configured to:
drive the first inverter and the second inverter, store first data in the first node, and store second data, which is inverted data of the first data, in the second node;
set the first inverter and the second inverter to an undriven state, and read the first data from the first node to the bus;
drive the first inverter, and write the first data based on the second data to the first node from which the first data is read; and
drive the second inverter after the first data is written.

9. The semiconductor memory device according to claim 8, further comprising:
a second latch circuit including: a third inverter that includes an input terminal coupled to a third node coupled to the bus and an output terminal coupled to a fourth node coupled to the bus; and a fourth inverter that includes an input terminal coupled to the fourth node and an output terminal coupled to the third node, wherein
the sequencer is further configured to:
drive the third inverter and the fourth inverter, store third data in the third node, and store fourth data, which is inverted data of the third data, in the fourth node; and
set the third inverter and the fourth inverter to the undriven state, and read the third data from the third node to the bus.

10. The semiconductor memory device according to claim 9, wherein the sequencer is further configured to perform an AND operation using the first data and the third data read out to the bus, and output fifth data, which is a result of the AND operation, to the sense circuit.

11. The semiconductor memory device according to claim 10, wherein the sequencer is further configured to:
drive the third inverter, and write the third data based on the fourth data to the third node from which the third data is read; and
drive the fourth inverter after the third data is written.

12. The semiconductor memory device according to claim 9, wherein the sequencer is further configured to perform an AND operation on the first data and the third data read out to the bus, and output fifth data, which is a result of the AND operation, to the third node.

13. The semiconductor memory device according to claim 12, wherein the sequencer is further configured to:
drive the fourth inverter after the fifth data is output to the third node, and write sixth data, which is inverted data of the fifth data, to the fourth node, and
drive the third inverter after the sixth data is written.

14. The semiconductor memory device according to claim 13, wherein a voltage of the fourth node is input to the sense circuit as a control signal.

15. The semiconductor memory device according to claim 13, wherein a voltage of the third node is input to the sense circuit as a control signal.

16. The semiconductor memory device according to claim 8, wherein the first latch circuit further includes:
a first transistor including a first end coupled to the first node and a second end coupled to the bus;
a second transistor including a first end coupled to the second node and a second end coupled to the bus:
a third transistor and a fourth transistor each including a first end coupled to the first node, a second end, and a gate end coupled to the second node;
a fifth transistor and a sixth transistor each including a first end coupled to the second node, a second end, and a gate end coupled to the first node;
a seventh transistor including a first end coupled to the second end of the third transistor; and
an eighth transistor including a first end coupled to the second end of the fifth transistor, wherein the fifth transistor and the sixth transistor function as the first inverter,
the third transistor and the fourth transistor function as the second inverter,
the first transistor controls coupling between the first node and the bus,
the second transistor controls coupling between the second node and the bus,
the seventh transistor controls driving of the second inverter, and
the eighth transistor controls driving of the first inverter.

17. The semiconductor memory device according to claim 16, wherein the second end of the fourth transistor and the second end of the sixth transistor are electrically decoupled from each other.

18. The semiconductor memory device according to claim 9, wherein
the second latch circuit further includes:
a ninth transistor including a first end coupled to the third node and a second end coupled to the bus;
a tenth transistor including a first end coupled to the fourth node and a second end coupled to the bus;
an eleventh transistor and a twelfth transistor each including a first end coupled to the third node, a second end, and a gate end coupled to the fourth node;
a thirteenth transistor and a fourteenth transistor each including a first end coupled to the fourth node, a second end, and a gate end coupled to the third node;
a fifteenth transistor including a first end coupled to the second end of the eleventh transistor; and
a sixteenth transistor including a first end coupled to the second end of the thirteenth transistor,
the thirteenth transistor and the fourteenth transistor function as the third inverter,
the eleventh transistor and the twelfth transistor function as the fourth inverter,
the ninth transistor controls coupling between the third node and the bus,
the tenth transistor controls coupling between the fourth node and the bus,
the fifteenth transistor controls driving of the fourth inverter, and
the sixteenth transistor controls driving of the third inverter.

19. The semiconductor memory device according to claim 18, wherein
the first latch circuit further includes:
a third transistor and a fourth transistor each including a first end coupled to the first node, a second end, and a gate end coupled to the second node; and
a fifth transistor and a sixth transistor each including a first end coupled to the second node, a second end, and a gate end coupled to the first node,
the fifth transistor and the sixth transistor function as the first inverter,
the third transistor and the fourth transistor function as the second inverter,
the second end of the fourth transistor, the second end of the sixth transistor, the second end of the twelfth transistor, and the second end of the fourteenth transistor are electrically decoupled from one another.

20. The semiconductor memory device according to claim 8, wherein
the semiconductor memory device is a NAND flash memory.
